(19) United States
(12) Patent Application Publication
(10) Pub. No.: US 2006/0182537 A1
(43) Pub. Date: Aug. 17, 2006

(54) Apparatus and process for placing a FOUP on a loadport

(75) Inventor: Gert Weniger, Jena (DE)

Correspondence Address: HOUSTON ELISEEVA, 4 MILITIA DRIVE, SUITE 4, LEXINGTON, MA, 02421, US

(73) Assignee: Leica Microsystems Jena GmbH, Jena (DE)

(21) Appl. No.: 11/316,495

(22) Filed: Dec. 22, 2005

(30) Foreign Application Priority Data
Dec. 24, 2004 (DE) 10 2004 062 591.3

(51) Int. Cl. H01L 21/677

(52) U.S. Cl. 414/217

(57) ABSTRACT

An apparatus for placing a FOUP on a loadport 20 of a system for processing disc-shaped objects is disclosed. Several light indicators 23 are provided at the loadport 20, which indicate a correct orientation and positioning of the FOUP on the loadport 20 as well as clearance to load or unload the loadport 20. A operating element 30 is arranged at the loadport, which when activated gives clearance for processing the disc-shaped objects in the FOUP.

### RELATED APPLICATIONS

This application claims priority to German patent application number DE 10 2004 062 591.3, filed Dec. 24, 2004, which is incorporated herein by reference in its entirety.

### FIELD OF INVENTION

And the invention relates to an apparatus for placing a FOUP on a loadport. In particular, the invention relates to an apparatus for placing a FOUP on a loadport of a system for processing disc-shaped objects, whereby several indicator lights are provided at the loadport, which indicate a correct orientation and positioning of the FOUP on the loadport as well as clearance to load or unload the loadport.

Furthermore, the invention relates to a process for placing a FOUP on a loadport.

### BACKGROUND OF THE INVENTION

In semiconductor manufacturing, wafers or disc-shaped substrates, respectively, are sequentially processed in a multiplicity of processing steps during the production process. The disc-shaped substrates are transported to the systems in containers, the FOUPs. The various processing steps are then carried out in the systems.

According to the state-of-the-art, FOUPs are placed on the loadports of the systems. The correct position and orientation of the FOUPs on the loadport is recognized by sensors and visualized for the operator by a lighting device. The FOUP may not be removed from the loadport when processing of the disc-shaped objects of the FOUP is being carried out. If this occurs nonetheless, this event is indicated by an optical or acoustic signal. The alarm can be switched off by the operator.

US patent application 2002/0155641 A1 discloses an apparatus for orienting a loadport in a processing machine. The apparatus has a base plate in which at least two vertical bore holes are implemented that interact with the corresponding pins in the processing machine. And orientation block is provided for orienting in which at least one horizontal borehole is provided. The orientation of the loadport is determined via the borehole by means of a light source and a detector.

### SUMMARY OF THE INVENTION

The object underlying the invention is to create an apparatus with which the FOUPs may be safely placed on unused loadports and removed from these at any time without triggering an alarm.

This object is solved by an apparatus for placing a FOUP on a loadport of a system for processing disc-shaped objects. The loadport comprises several indicator lights that indicate a correct orientation and positioning of the FOUP on the loadport and clearance to load or unload the loadport. Furthermore, a operating element is arranged at the loadport, which, when activated, gives clearance for processing the disc-shaped objects in the FOUP.

A further object of the invention is to make available a process that enables the FOUPs to be placed safely and allows the FOUPs to the switched at will without triggering an alarm.

This object is solved by a process with the following characteristics:
placing a FOUP on an unused loadport;
checking the correct orientation of the FOUP on the loadport;
checking the activity of a operating element 30 that is provided at a loadport 20; and
allowing multiple placements and/or removals of the FOUP when the operating element 30 is activated.

It is particularly advantageous if the loadport is implemented such that FOUPs may be placed on it before, for example, processing occurs in another system. The apparatus for placing a FOUP on a loadport of a system for processing disc-shaped objects is provided with several light indicators at the loadport. The light indicators indicate the correct orientation and positioning of the FOUP on the loadport. The type and correct positioning of the FOUP may be determined by means of sensors. An operating element is arranged at the loadport, which when activated gives clearance for processing the disc-shaped objects in the FOUP.

The operating element is provided with a light that indicates that processing of the disc-shaped objects has not yet started, and that the FOUP may therefore be removed at any time. The loadport is implemented in accordance with SEMI E15 and interlocks with a bottom side of the FOUP.

The process for placing a FOUP on a loadport comprises the following steps: setting a FOUP on an unused loadport; checking the correct orientation of the FOUP on the loadport; checking the activity of an operating element provided at a loadport; and allowing multiple placements and/or removals of the FOUP when the operating element is activated. The activity of the operating element is indicated by a light in the operating element. Activated, i.e., lit operating elements, enable and permit multiple placements and/or removals of the FOUP from loadport.

Further advantageous developments of the invention may be inferred from the subclaims.

The above and other features of the invention including various novel details of construction and combinations of parts, and other advantages, will now be more particularly described with reference to the accompanying drawings and pointed out in the claims. It will be understood that the particular method and device embodying the invention are shown by way of illustration and not as a limitation of the invention. The principles and features of this invention may be employed in various and numerous embodiments without departing from the scope of the invention.

### BRIEF DESCRIPTION OF THE DRAWINGS

In the accompanying drawings, reference characters refer to the same parts throughout the different views. The drawings are not necessarily to scale; emphasis has instead been placed upon illustrating the principles of the invention. Of the drawings:

The subject of the invention is schematically represented in the diagram and is described below based on the figures. They show:

FIG. 1 a schematic view of a first embodiment of the system, comprising a microinspection device and a macroinspection device;

FIG. 2 a perspective view of a loadport connected to a system for processing disc-shaped substrates;

FIG. 3 a perspective view of a loadport with the operating element according to the invention;

FIG. 4 a schematic view of the operating element that is provided on the base plate of the loadport; and

FIG. 5 a schematic representation of a flow diagram of the process according to the invention.

### DETAILED DESCRIPTION OF THE PREFERRED EMBODIMENTS

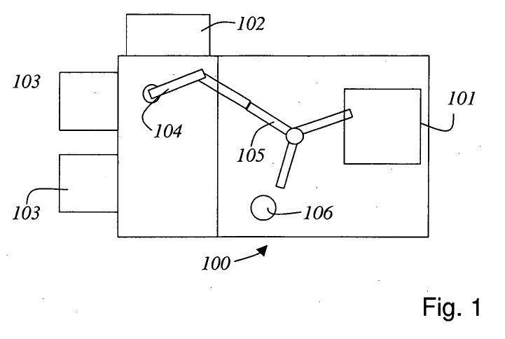

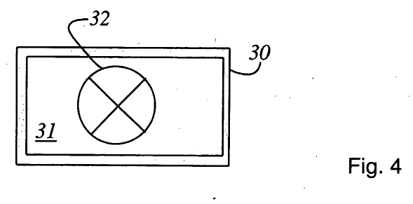

FIG. 1 shows a schematic view of a first embodiment of the system 100, comprising a microinspection device 101 and a macroinspection device 102. The macroinspection device 102 is implemented as a module and can therefore be quickly and simply connected to the system 100. The front side and back side 2, 3 of a disc-shaped object 4 (see FIG. 4) are imaged in the macroinspection device 102. Furthermore, the system 100 is provided with at least one FOUP 103 via which the disc-shaped objects 4 are transported to and from the system 100. The system is provided with a handler 104 that removes the disc-shaped objects 4 from the FOUPs 103 and places them in the FOUPs 103, or transfers them on to the macroinspection device 102 or two a three-paddle handler 105. The system 100 represented in FIG. 1 comprises a first transfer position, a second transfer position, and a third transfer position. The three-paddle handler 105 takes the disc-shaped object 4 from the handler 104 at the first transfer position. At the second transfer position, there is a pre-aligner 106 that takes the disc-shaped objects 4 from the three-paddle handler 105. At the third transfer position, the microinspection device 101 takes the disc-shaped objects from the three-paddle handler 105. It is evident that the aforedescribed system 100 is not limited to this concrete embodiment. Many other arrangements are conceivable in which one or several FOUPs 103 may interact with the system 100 for processing disc-shaped objects.

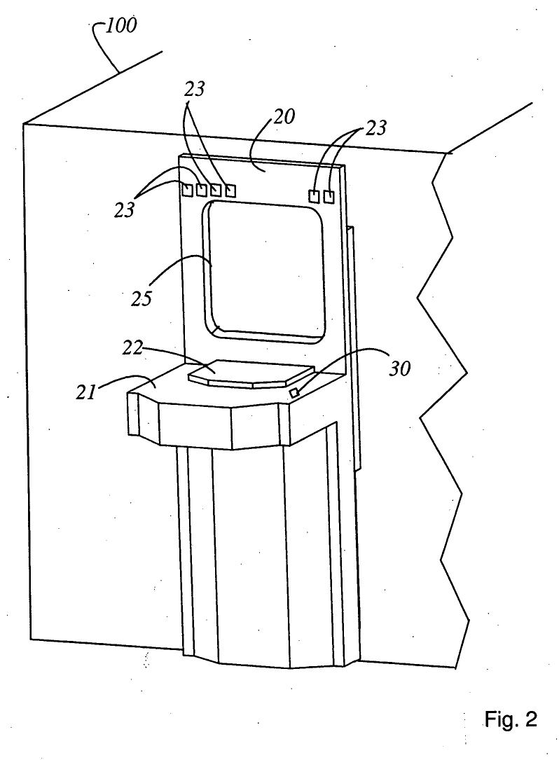

FIG. 2 is a perspective view of a loadport 20 connected to a system 100 for processing disc-shaped substrates. The loadport 20 is connected with the system 100, and therefore forms an interface between the system 100 for processing the disc-shaped substrates. The loadport 20 is provided with a base plate 21 onto which a FOUP (not represented) 101 can be placed. The base plate 21 itself bears a connection plate 22 that is implemented in accordance with the SEMI E15 standard and interlocks with a bottom side (not represented) of the FOUP 101. By interlocking, the FOUP 101 is securely seated on the loadport 20. In addition to the aforedescribed interlocking, coupling elements (not represented) between the FOUP 101 and a loadport 20 grip each other to achieve a secure seat. A FOUP 101 filled with disc-shaped objects can therefore not be accidentally knocked off of the loadport 20, so that an additional level of security to protect the disc-shaped objects is built in. In addition, several light indicators 23 are provided at the loadport 20, which indicate the correct positioning of the FOUP 101 on the loadport 20. Similarly, the light indicators 23 indicate whether the FOUP 101 has been placed on the loadport or whether the present FOUP may be removed. In addition, an opening 25 is provided in the loadport 20, via which the disc-shaped objects are transported from the FOUP to the system 100.

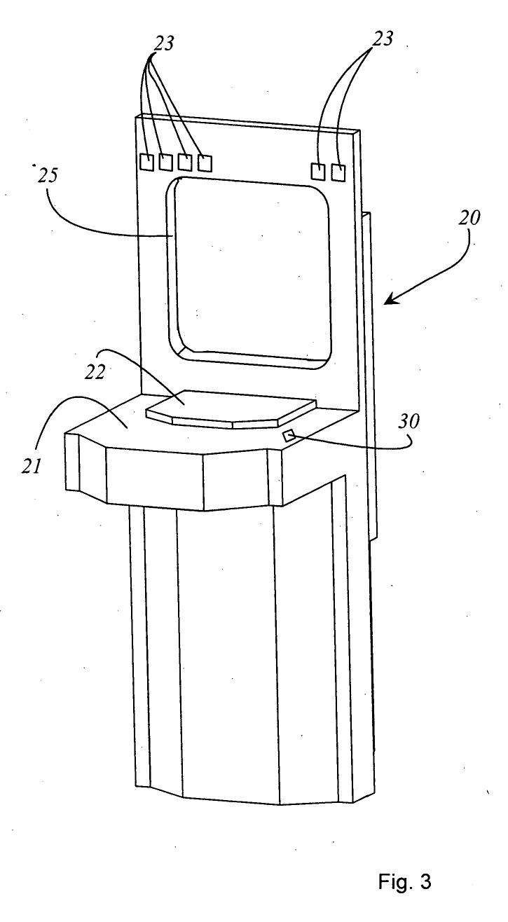

FIG. 3 is a perspective view of the loadport 20 with the operating element 30 according to the invention. The operating element 30 makes it possible for a FOUP 101 to be placed on the loadport without initializing the lock device, by means of which the FOUP 101 is prevented from being removed before the disc-shaped objects contained in the FOUP 101 have been processed by the system 100. Once the operator has placed a FOUP 101 on the loadport and presses or activates the operating element 30, the disc-shaped objects contained in the FOUP 101 are processed. If the operator parks a FOUP 101 on the loadport 20 without activating the operating element 30, the FOUP 101 is secured and fixed on the loadport 20 and can be removed and lowered again as desired.

FIG. 4 is a schematic view of an operating element 30 that is provided on the base plate 21 of the loadport 20. The operating element 30 is provided with an internal light, which indicates that processing of the disc-shaped objects has not yet started, so that the FOUP may be removed from the loadport 20 at any time. The operating element 30 further comprises an activation element 31, via which activation or deactivation, respectively, of the operating element 30 may be undertaken.

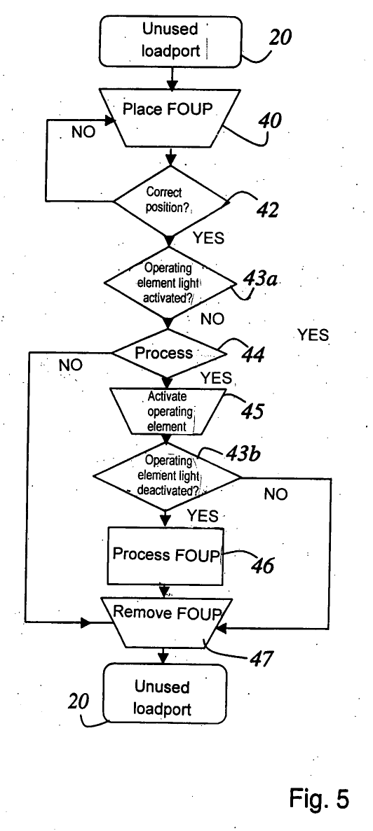

FIG. 5 is a schematic representation of a flow diagram of the process according to the invention. A free or unused loadport 20 is available. In a first step 40, the operator can place or remove a FOUP on this loadport 20. At this time, the loadport 20 tests to determine whether the FOUP is correctly placed. If the FOUP is not correctly placed, this can be corrected. In a first status inquiry 42, the position of the FOUP is determined. Subsequently a status inquiry 43a determines whether the light 33 in the operating element 30 is activated. If this is not the case, the process may be resumed, and a second status inquiry 44 determines whether the disc-shaped substrates in the FOUP may be processed or not. The decision whether to process or not is initiated by activating 45 the operating element 30. In a further status inquiry 43b, it is determined whether the light 33 in the operating element 30 is deactivated. If the light 33 in the operating element 30 is deactivated, then the disc-shaped objects in the FOUP are processed. Processing 46 of the FOUP ensues. Once processing is concluded, the FOUP may be removed from the loadport 20. In other words, the FOUP is removed 47 from the loadport 20. If the operating element 30 is not pressed, the FOUP may then be removed from the loadport 20 at any time.

While this invention has been particularly shown and described with references to preferred embodiments thereof, it will be understood by those skilled in the art that various changes in form and details may be made therein without departing from the scope of the invention encompassed by the appended claims.

What is claimed is:

1. Apparatus for placing a FOUP on a loadport of a system for processing disc-shaped objects, wherein the loadport comprises several light indicators that indicate a correct orientation and positioning of the FOUP on the loadport and indicate clearance to load or unload the loadport, and wherein an operating element is arranged at the loadport that when activated gives clearance for processing the disc-shaped objects in the FOUP.

2. Apparatus according to claim 1, wherein the operating element is provided with an internal light that indicates that processing of the disc-shaped objects has not started, so that the FOUP may be removed from the loadport at any time.

3. Apparatus according to claim 1, wherein the disc-shaped object is a wafer, or a wafer on a glass substrate, or a mask for lithography, or a flat-panel display.

4. Apparatus according to claim 1, wherein the loadport is implemented in accordance with SEMI E15 and interlocks with the bottom side of the FOUP.

5. Process for placing a FOUP on a loadport, characterized by the following steps:
placing a FOUP on an unused loadport;
checking the correct orientation of the FOUP on the loadport;
checking the activity of an operating element 30 that is provided at a loadport 20; and
allowing multiple placements and/or removals of the FOUP when the operating element 30 is activated.

6. Process according to claim 5, wherein the activity of the operating element is indicated by an internal light in the operating element.

7. Process according to claim 5, wherein the disc-shaped objects in the FOUP are processed when the operating element is activated.

8. Process according to claim 7, wherein the FOUP may be removed from the loadport after processing of the disc-shaped objects in the FOUP is concluded.

9. Process according to claim 8, wherein the FOUP may be securely seated on the loadport when the operating element is not activated and the LOAD indicator is activated, and wherein the FOUP may be removed any number of times when the operating element is not activated and the UNLOAD indicator is activated.

10. Process according to claim 5, wherein the disc-shaped object is a wafer, or a wafer on a glass substrate, or a mask for lithography, or a flat-panel display.
